(19) United States
(12) Patent Application Publication
(10) Pub. No.: US 2025/0107136 A1
(43) Pub. Date: Mar. 27, 2025

(54) SEMICONDUCTOR DEVICE

(71) Applicant: Samsung Electronics Co., Ltd., Suwon-si (KR)

(72) Inventors: Hyeok-Jun SON, Suwon-si (KR); Chan Hyeong LEE, Suwon-si (KR)

(21) Appl. No.: 18/628,220

(22) Filed: Apr. 5, 2024

(30) Foreign Application Priority Data
Sep. 26, 2023 (KR) 10-2023-0129420

(51) Int. Cl. H01L 29/78; H01L 29/423; H01L 29/66

(52) U.S. Cl. CPC H10D 30/6215; H10D 64/514; H10D 30/024

(57) ABSTRACT

Provided a semiconductor device. The semiconductor device comprises an active pattern extending in a first direction on a substrate, a gate stack extending in a second direction intersecting the first direction on the active pattern, and a source/drain pattern on at least one side of the gate stack, wherein the gate stack includes a first work function pattern, a second work function pattern on the first work function pattern, and a diffusion prevention pattern between the first work function pattern and the second work function pattern, and wherein a concentration of aluminum in the second work function pattern is greater than a concentration of aluminum in the first work function pattern.

### CROSS-REFERENCE TO RELATED APPLICATION

This application claims priority from Korean Patent Application No. 10-2023-0129420 filed on Sep. 26, 2023 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a semiconductor device.

### 2. Description of the Related Art

As one of the scaling technologies for increasing a density of semiconductor devices, a multi-gate transistor in which a multi-channel active pattern (or silicon body) having a fin or nanowire shape is formed on a substrate and a gate is formed on a surface of the multi-channel active pattern has been proposed.

Since such a multi-gate transistor uses a three-dimensional channel, it is easy to perform scaling. In addition, it is possible to improve current control capability even without increasing a length of the gate of the multi-gate transistor. In addition, it is possible to effectively suppress a short channel effect (SCE) in which a potential of a channel region is affected by a drain voltage.

Meanwhile, in a PMOS region, if an N-type metal diffuses from an N-type work function metal to a P-type work function metal, a problem of reduced reliability may occur. Research to solve such a problem is being conducted.

### SUMMARY

Aspects of the present disclosure provide a semiconductor device capable of having improved reliability.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a semiconductor device comprising, an active pattern extending in a first direction on a substrate, a gate stack extending in a second direction intersecting the first direction on the active pattern, and a source/drain pattern on at least one side of the gate stack, wherein the gate stack includes a first work function pattern, a second work function pattern on the first work function pattern, and a diffusion prevention pattern between the first work function pattern and the second work function pattern, and wherein a concentration of aluminum in the second work function pattern is greater than a concentration of aluminum in the first work function pattern.

According to another aspect of the present disclosure, there is provided a semiconductor device comprising a lower pattern extending in a first direction on a substrate, a plurality of sheet patterns spaced apart from each other in a third direction on the lower pattern, a gate stack extending in a second direction on the lower pattern and surrounding the plurality of sheet patterns, and a source/drain pattern on at least one side of the gate stack, the source/drain pattern being connected to the plurality of sheet patterns, wherein the gate stack includes an inner stack between adjacent sheet patterns among the plurality of sheet patterns and between the plurality of sheet patterns and the lower pattern, and an outer stack on the plurality of sheet patterns, wherein the outer stack of the gate stack includes a first work function pattern, a second work function pattern on the first work function pattern, and a diffusion prevention pattern between the first work function pattern and the second work function pattern, the diffusion prevention pattern being formed of silicon (Si), wherein the inner stack of the gate stack includes only the first work function pattern without including the second work function pattern and without including the diffusion prevention pattern, wherein a concentration of aluminum in the second work function pattern is greater than a concentration of aluminum in the first work function pattern, and wherein the first direction, the second direction, and the third direction intersect each other.

According to another aspect of the present disclosure, there is provided a semiconductor device comprising a substrate including a PMOS region and an NMOS region, a first lower pattern, on the PMOS region of the substrate, extending in a first direction, a plurality of first sheet patterns, on the first lower pattern, spaced apart from each other in a third direction, a first gate structure, on the PMOS region, extending in a second direction of the substrate and surrounding the plurality of first sheet patterns, a first source/drain pattern on at least one side of the first gate structure, the first source/drain pattern being connected to the plurality of first sheet patterns and including P-type impurities, a second lower pattern, on the NMOS region of the substrate, extending in the first direction, a plurality of second sheet patterns, on the second lower pattern, spaced apart from each other in the third direction, a second gate structure, on the NMOS region, extending in the second direction and surrounding the plurality of second sheet patterns, and a second source/drain pattern on at least one side of the second gate structure, the second source/drain pattern being connected to the plurality of second sheet patterns and including N-type impurities, wherein the first gate structure includes a first gate insulating film, a P-type work function pattern in contact with the first gate insulating film, a first N-type work function pattern on the P-type work function pattern, a diffusion prevention pattern between the P-type work function pattern and the first N-type work function pattern, and a first capping pattern between the first N-type work function pattern and the diffusion prevention pattern, wherein the second gate structure includes a second gate insulating film, a second capping pattern in contact with the second gate insulating film, and a second N-type work function pattern on the second capping pattern, wherein the first N-type work function pattern and the second N-type work function pattern are formed of the same material, wherein a concentration of aluminum in the P-type work function pattern is greater than a concentration of aluminum in the first N-type work function pattern, and wherein the first direction, the second direction, and the third direction intersect each other.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is an exemplary plan view for describing a semiconductor device according to some exemplary embodiments.

FIG. 2 is an exemplary cross-sectional view taken along line A-A of FIG. 1.

FIG. 3 is an enlarged view of region P of FIG. 2.

FIG. 4 is an exemplary cross-sectional view taken along line B-B of FIG. 1.

FIG. 5 is an enlarged view of region Q of FIG. 4.

FIG. 6 is an exemplary cross-sectional view taken along line C-C of FIG. 1.

FIGS. 7 to 9 are views for describing a semiconductor device according to some other exemplary embodiments of the present disclosure.

FIG. 10 is an exemplary plan view for describing a semiconductor device according to some other exemplary embodiments of the present disclosure.

FIG. 11 is an exemplary cross-sectional view taken along line D-D of FIG. 10.

FIG. 12 is an exemplary cross-sectional view taken along line E-E of FIG. 10.

FIG. 13 is an exemplary cross-sectional view taken along line F-F of FIG. 10.

FIGS. 14 to 27 are intermediate step views for describing a method for fabricating a semiconductor device according to some exemplary embodiments of the present disclosure.

### DETAILED DESCRIPTION OF THE EMBODIMENTS

It will be understood that, although the terms first, second, etc. may be used herein to describe various elements or components, these elements or components should not be limited by these terms. These terms are only used to distinguish one element or component from another element or component. Therefore, a first element or component mentioned below may also be a second element or component within the technical spirit of the present disclosure.

In the drawings of a semiconductor device according to some exemplary embodiments, a fin-type transistor (FinFET) including a channel region having a fin-type pattern shape, a transistor including nanowires or nanosheets, a multi-bridge channel field effect transistor (MBCFET™), or vertical FET is exemplarily illustrated, but the present disclosure is not limited thereto. The semiconductor device according to some exemplary embodiments may include a tunneling FET or a three-dimensional (3D) transistor. The semiconductor device according to some exemplary embodiments may include a planar transistor. In addition, a technical idea of the present disclosure may be applied to two-dimensional (2D) material based FETs and a heterostructure thereof.

In addition, the semiconductor device according to some exemplary embodiments may also include a bipolar junction transistor, a lateral double-diffused metal oxide semiconductor (LDMOS) transistor, or the like.

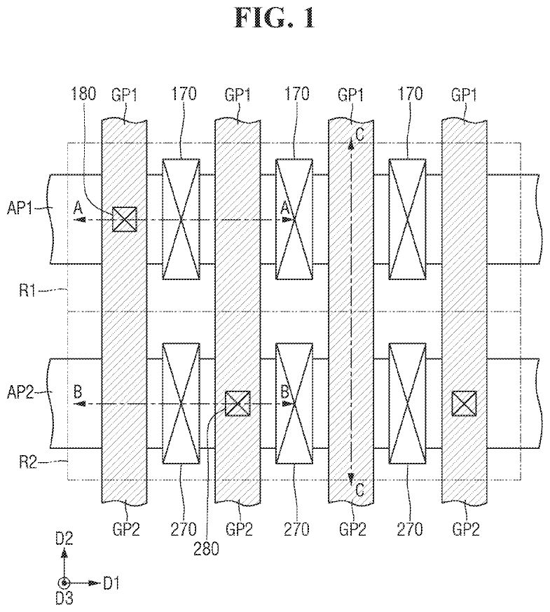

Hereinafter, exemplary embodiments of the present disclosure will be described with reference to the accompanying drawings. First, a semiconductor device according to some exemplary embodiments of the present disclosure will be described with reference to FIGS. 1 to 6.

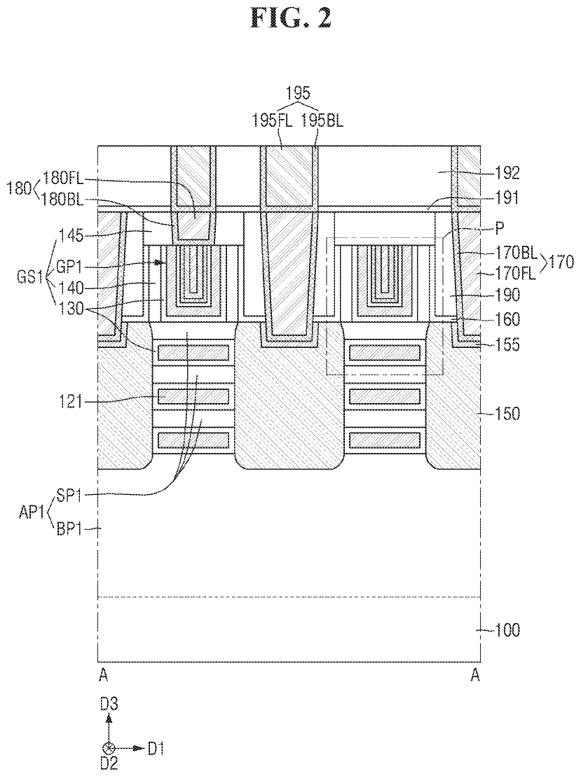

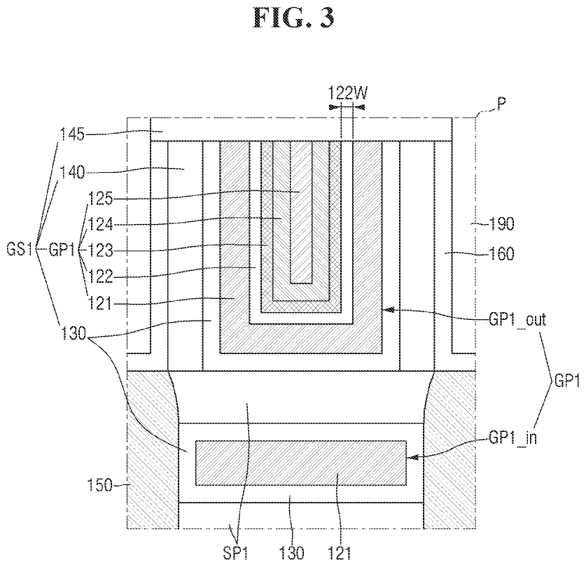

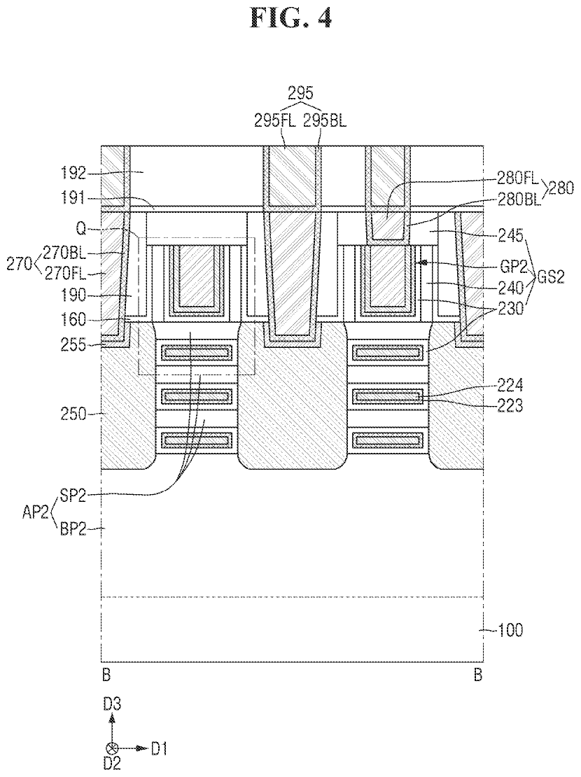

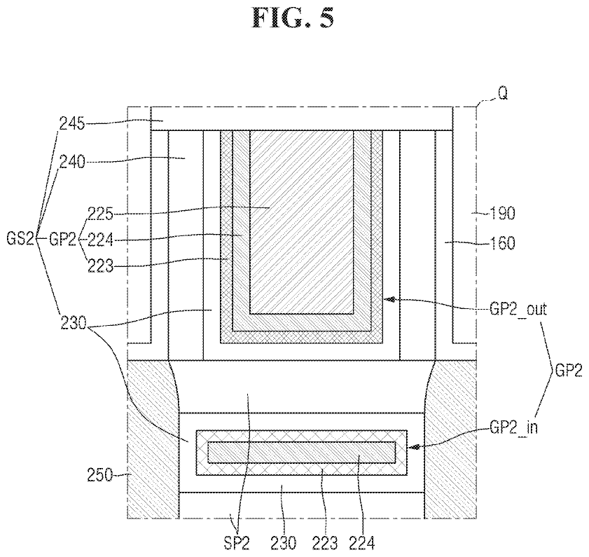

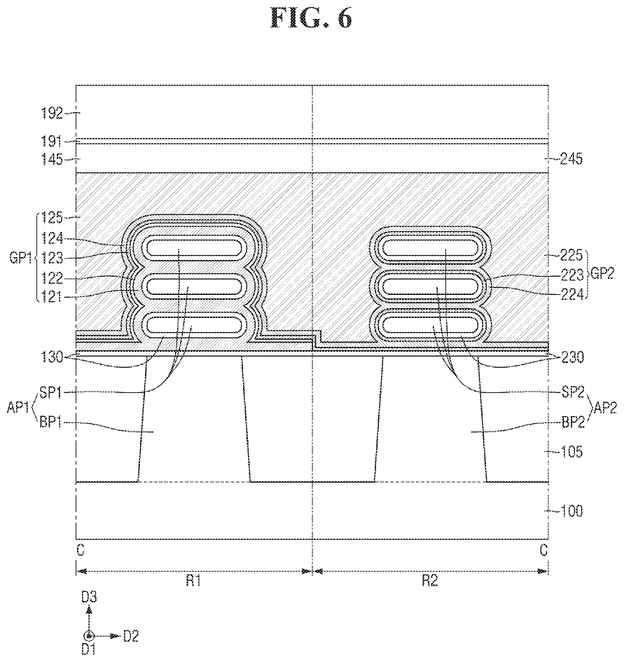

FIG. 1 is an exemplary plan view for describing a semiconductor device according to some exemplary embodiments. FIG. 2 is an exemplary cross-sectional view taken along line A-A of FIG. 1. FIG. 3 is an enlarged view of region P of FIG. 2. FIG. 4 is an exemplary cross-sectional view taken along line B-B of FIG. 1. FIG. 5 is an enlarged view of region Q of FIG. 4. FIG. 6 is an exemplary cross-sectional view taken along line C-C of FIG. 1.

Referring to FIGS. 1 to 6, a semiconductor device according to some exemplary embodiments may include a first active pattern AP1, a second active pattern AP2, a plurality of first gate stacks GP1, a plurality of second gate stacks GP2, a first source/drain contact 170, a second source/drain contact 270, a first gate contact 180, and a second gate contact 280.

First, a substrate 100 may be provided. The substrate 100 may include a first region R1 and a second region R2. In some exemplary embodiments, the first region R1 may be a PMOS region and the second region R2 may be an NMOS region. The substrate 100 may be bulk silicon or silicon-on-insulator (SOI). Alternatively, the substrate 100 may be a silicon substrate, and may include, but is not limited to, another material, for example, silicon germanium, silicon germanium on insulator (SGOI), indium antimonide, lead tellurium compound, indium arsenide, indium phosphide, gallium arsenide, or gallium antimonide.

The first active pattern AP1 and the second active pattern AP2 may be disposed on the substrate 100. The first active pattern AP1 may be disposed on the first region R1. The first active patterns AP1 may be disposed on the PMOS region. The second active pattern AP2 may be disposed on the second region R2. The second active patterns AP2 may be disposed on the NMOS region. The first active pattern AP1 and the second active pattern AP2 may each extend along a first direction D1 on the substrate 100. An item, layer, or portion of an item or layer described as “extending” in a particular direction has a length in the particular direction and a width perpendicular to that direction, where the length is greater than the width. The first active pattern AP1 and the second active pattern AP2 may be spaced apart from each other in a second direction D2.

In plan view, the first active pattern AP1 and the second active pattern AP2 may each include a long side extending in the first direction D1 and a short side extending in the second direction D2. Here, the first direction D1 may intersect the second direction D2. In addition, herein, a third direction D3 may intersect the first direction D1 and the second direction D2. The third direction D3 may be a thickness direction of the substrate 100.

The first active pattern AP1 and the second active pattern AP2 may each be a multi-channel active pattern. The first active pattern AP1 may include a first lower pattern BP1 and a plurality of first sheet patterns SP1. The second active pattern AP2 may include a second lower pattern BP2 and a plurality of second sheet patterns SP2.

The first lower pattern BP1 may protrude from the substrate 100 in the third direction D3. The first lower pattern BP1 may extend in the first direction D1. The first lower pattern BP1 may be a fin-shaped pattern. The plurality of first sheet patterns SP1 may be disposed on the first lower pattern BP1. The plurality of first sheet patterns SP1 may be spaced apart from the first lower pattern BP1 in the third direction D3. In addition, the plurality of first sheet patterns SP1 may be spaced apart from each other in the third direction D3. It is illustrated that three first sheet patterns SP1 are disposed in the third direction D3, but this is only for convenience of explanation, and the number of first sheet patterns SP1 is not limited thereto.

The second lower pattern BP2 may protrude from the substrate 100 in the third direction D3. The second lower pattern BP2 may extend in the first direction D1. The second lower pattern BP2 may be a fin-shaped pattern. The plurality of second sheet patterns SP2 may be disposed on the second lower pattern BP2. The plurality of second sheet patterns SP2 may be spaced apart from the second lower pattern BP2 in the third direction D3. In addition, the plurality of second sheet patterns SP2 may be spaced apart from each other in the third direction D3. It is illustrated that three second sheet patterns SP2 are disposed in the third direction D3, but this is only for convenience of explanation, and the number of second sheet patterns SP2 is not limited thereto.

The first lower pattern BP1 and the second lower pattern BP2 may each be formed by etching a portion of the substrate 100, and may include an epitaxial layer grown from the substrate 100. The first lower pattern BP1 and the second lower pattern BP2 may each be formed of or include silicon or germanium, which is an elemental semiconductor material. In addition, the first lower pattern BP1 and the second lower pattern BP2 may each include a compound semiconductor, for example, a group IV-IV compound semiconductor or a group III-V compound semiconductor.

The group IV-IV compound semiconductor may be, for example, a binary compound or a ternary compound including at least two or more of carbon (C), silicon (Si), germanium (Ge), and tin (Sn), or a compound obtained by doping carbon (C), silicon (Si), germanium (Ge), and tin (Sn) with a group IV element.

The III-V compound semiconductor may be, for example, one of a binary compound, a ternary compound, or a quaternary compound formed by combining at least one of aluminum (Al), gallium (Ga), and indium (In), which are group III elements, and one of phosphorus (P), arsenic (As), and antimony (Sb), which are group V elements.

The first sheet patterns SP1 and the second sheet patterns SP2 may each be formed of or include one of silicon or germanium, which is an elemental semiconductor material, a group IV-IV compound semiconductor, or a group III-V compound semiconductor. Each first sheet pattern SP1 may also include the same material as the first lower pattern BP1 or a material different from that of the first lower pattern BP1. Each second sheet pattern SP2 may also include the same material as the second lower pattern BP2 or a material different from that of the second lower pattern BP2.

In the semiconductor device according to some exemplary embodiments, the first lower pattern BP1 and the second lower pattern BP2 may be silicon lower patterns containing silicon, and the first sheet pattern SP1 and the second sheet pattern SP2 may be silicon sheet patterns containing silicon.

A field insulating film 105 may be formed on the substrate 100 (see, e.g., FIG. 6). The field insulating film 105 may cover a sidewall of the first lower pattern BP1 and a sidewall of the second lower pattern BP2. Each first sheet pattern SP1 and each second sheet pattern SP2 are disposed to be higher than an upper surface of the field insulating film 105. The field insulating film 105 may be formed of or include, for example, an oxide film, a nitride film, an oxynitride film, or a combination thereof. The field insulating film 105 is illustrated as a single film, but is not limited thereto. Unlike illustrated, the field insulating film 105 may also include a field liner extending along a sidewall and a bottom surface of a fin trench defining the first and second lower patterns BP1 and BP2, and a field filling film on the field liner.

The plurality of first gate structures GS1 may be disposed on the first active pattern AP1. The plurality of first gate structures GS1 may be disposed on the first region R1. The plurality of first gate structures GS1 may be disposed on the PMOS region. The plurality of first gate structures GS1 may intersect the first active pattern AP1. The plurality of first gate structures GS1 may extend in the second direction D2. The plurality of first gate structures GS1 may be spaced apart from each other in the first direction D1.

The plurality of first gate structures GS1 may each include a first gate insulating film 130, a first gate stack GP1, a first gate spacer 140, and a first gate capping film 145.

The first gate stack GP1 may be disposed on the first lower pattern BP1. The first gate stack GP1 may surround the plurality of first sheet patterns SP1.

The first gate stack GP1 may include a first work function pattern 121, a diffusion prevention pattern 122, a first capping pattern 123, a second work function pattern 124, and a first filling pattern 125 (see, e.g., FIG. 3).

The first work function pattern 121, the diffusion prevention pattern 122, the first capping pattern 123, the second work function pattern 124, and the first filling pattern 125 may be sequentially stacked. For example, the diffusion prevention pattern 122 may be disposed on the first work function pattern 121. The first capping pattern 123 may be disposed on the diffusion prevention pattern 122. The second work function pattern 124 may be disposed on the first capping pattern 123. The first filling pattern 125 may be disposed on the second work function pattern 124. The first work function pattern 121, the diffusion prevention pattern 122, the first capping pattern 123, the second work function pattern 124, and the first filling pattern 125 may each be a single homogenous layer (formed of the same base material throughout). For example, these patterns may each be formed with a single corresponding process (e.g., in situ-in a chamber without vacuum break to the chamber). It should be appreciated that a homogenous layer is contemplated to allow for different doping levels/concentrations in such a layer.

The first work function pattern 121 may be disposed at the lowest portion of the first gate stack GP1. The first work function pattern 121 may be in contact with the first gate insulating film 130. It will be understood that when an element is referred to as “contacting” or “in contact with” another element (or using any form of the word “contact”), there are no intervening elements present at the point of contact. The first work function pattern 121 may be disposed in a ‘U’ shape along a profile of the first gate insulating film 130. A thickness of the first work function pattern 121 may be constant along the ‘U’ shape, but is not limited thereto.

The first work function pattern 121 may be formed of or include a metal nitride film with a relatively high work function. In other words, the first work function pattern 121 may include a P-type work function metal. That is, the first work function pattern 121 may be a P-type work function pattern. For example, the first work function pattern 121 may include at least one of a titanium nitride film (TiN), a tantalum nitride film (TaN), a titanium oxynitride film (TiON), a titanium silicon nitride film (TiSiN), a titanium aluminum nitride film (TiAlN), a tungsten carbon nitride film (WCN), and a molybdenum nitride film (MoN).

As an example, the first work function pattern 121 may include aluminum. As another example, the first work function pattern 121 may not include aluminum. A concentration of aluminum included in the first work function pattern 121 may be lower than a concentration of aluminum included in the second work function pattern 124.

The diffusion prevention pattern 122 may be disposed on the first work function pattern 121. The diffusion prevention pattern 122 may be disposed between the first work function pattern 121 and the second work function pattern 124. The diffusion prevention pattern 122 may be in contact with the first work function pattern 121. The diffusion prevention pattern 122 may not be in contact with the second work function pattern 124. The diffusion prevention pattern 122 may be disposed in a ‘U’ shape along a profile of the first work function pattern 121. A thickness of the diffusion prevention pattern 122 may be constant along the ‘U’ shape.

The diffusion prevention pattern 122 may prevent aluminum included in the second work function pattern 124 from diffusing into the first work function pattern 121. Since the diffusion prevention pattern 122 prevents diffusion of aluminum, unintended changes in work function due to aluminum diffusion may be minimized. Accordingly, a semiconductor device having improved reliability may be provided.

In some exemplary embodiments, the diffusion prevention pattern 122 may be formed of or include silicon (Si). The thickness 122W of the diffusion prevention pattern 122 may be 3 Å or more and 10 Å or less. When the thickness 122W of the diffusion prevention pattern 122 is smaller than 3 Å, aluminum may pass through the diffusion prevention pattern 122 and diffuse into the first work function pattern 121. In addition, when the thickness 122W of the diffusion prevention pattern 122 is greater than 10 Å, it may be disadvantageous in terms of integration of the semiconductor device.

The first capping pattern 123 may be disposed on the diffusion prevention pattern 122. The first capping pattern 123 may be interposed between the diffusion prevention pattern 122 and the second work function pattern 124. A thickness of the first capping pattern 123 may be greater than the thickness 122W of the diffusion prevention pattern 122. However, the thickness of the first capping pattern 123 may be smaller than the thickness of the second work function pattern 124. The first capping pattern 123 may be formed of or include, for example, tungsten (W) or titanium nitride film (TiN).

The second work function pattern 124 may be disposed on the first capping pattern 123. The second work function pattern 124 may be disposed between the first capping pattern 123 and the first filling pattern 125. The second work function pattern 124 may be disposed in a ‘U’ shape along a profile of the first capping pattern 123. A thickness of the second work function pattern 124 may be constant along the ‘U’ shape, but is not limited thereto. The thickness of the second work function pattern 124 may be smaller than that of the first work function pattern 121. However, the technical spirit of the present disclosure is not limited thereto.

The second work function pattern 124 may be formed of or include metal carbide with a relatively low work function. In other words, the second work function pattern 124 may include an N-type work function metal. That is, the second work function pattern 124 may be a first N-type work function pattern. For example, the second work function pattern 124 may include at least one of aluminum-doped titanium carbide (TiAlC), aluminum-doped tantalum carbide (TaAlC), aluminum-doped vanadium carbide (VAlC), aluminum and silicon-doped titanium carbide (TiAlSiC), and aluminum and silicon doped tantalum carbide (TaAlSiC).

That is, the second work function pattern 124 may include aluminum. In this case, a concentration of aluminum included in the second work function pattern 124 may be greater than a concentration of aluminum included in the first work function pattern 121. Accordingly, without the diffusion prevention pattern 122, aluminum included in the second work function pattern 124 may diffuse toward the first work function pattern 121. In an embodiment, the diffusion prevention pattern 122 may prevent diffusion of aluminum.

The first filling pattern 125 may be disposed on the second work function pattern 124. The first filling pattern 125 may fill a trench remaining after the first work function pattern 121, the diffusion prevention pattern 122, the first capping pattern 123, and the second work function pattern 124 are formed. The first filling pattern 125 may be formed of or include, for example, tungsten (W) or titanium nitride film (TiN).

The plurality of first gate stacks GP1 may be disposed on both sides of a first source/drain pattern 150, which will be described later. As an example, the plurality of first gate stacks GP1 disposed on both sides of the first source/drain pattern 150 may be normal gate electrodes used as gates of transistors. As another example, the first gate stack GP1 disposed on one side of the first source/drain pattern 150 is used as the gate of the transistor, but the first gate stack GP1 disposed on the other side of the first source/drain pattern 150 may be a dummy gate electrode.

In some exemplary embodiments, the first gate stack GP1 may include an outer stack GP1_out and an inner stack GP1_in. For example, in FIG. 3, the outer stack GP1_out of the first gate stack GP1 may be disposed on the uppermost sheet pattern of the plurality of first sheet patterns SP1. The inner stack GP1_in of the first gate stack GP1 may be disposed between adjacent sheet patterns among the plurality of first sheet patterns SP1. In addition, the inner stack GP1_in of the first gate stack GP1 may be disposed between the first sheet pattern SP1 and the first lower pattern BP1.

The outer stack GP1_out of the first gate stack GP1 may be disposed in a trench defined by the first gate insulating film 130 and the first gate capping film 145. The outer stack GP1_out of the first gate stack GP1 may include a first work function pattern 121, a diffusion prevention pattern 122, a first capping pattern 123, a second work function pattern 124, and a first filling pattern 125. The inner stack GP1_in of the first gate stack GP1 may be disposed in a space defined by the first gate insulating film 130. The inner stack GP1_in of the first gate stack GP1 may include only the first work function pattern 121.

That is, the inner stack GP1_in of the first gate stack GP1 may not include the second work function pattern 124. Therefore, in the inner stack GP1_in of the first gate stack GP1, aluminum in the second work function pattern 124 does not diffuse into the first work function pattern 121.

According to some exemplary embodiments, since the outer stack GP1_out of the first gate stack GP1 includes the diffusion prevention pattern 122 and the inner stack GP1_in of the first gate stack GP1 does not include the second work function pattern 124, the work function in the outer stack GP1_out of the first gate stack GP1 and the work function in the inner stack GP1_in of the first gate stack GP1 may be kept constant. Accordingly, a semiconductor device having improved reliability may be provided.

A plurality of first gate spacers 140 may be disposed on the sidewall of each of the plurality of first gate stacks GP1. The plurality of first gate spacers 140 are not in contact with the plurality of first gate stacks GP1. The first gate insulating film 130 may be disposed between the first gate spacer 140 and the sidewall of the first gate stack GP1. The plurality of first gate spacers 140 may be formed of or include, for example, at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and a combination thereof.

The first gate insulating film 130 may extend between the first gate stacks GP1 and an upper surface of the field insulating film 105, between the first gate stacks GP1 and an upper surface of the first lower pattern BP1, and between the first gate stacks GP1 and the first sheet patterns SP1. The first gate insulating film 130 may be formed between the first gate stacks GP1 and the first gate spacers 140. In addition, the first gate insulating film 130 may also be formed between the first source/drain pattern 150 and the first gate stacks GP1.

The first gate insulating film 130 may be formed of or include silicon oxide, silicon oxynitride, silicon nitride, or a high-k material having a dielectric constant greater than that of silicon oxide. The high-k material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

It is illustrated that the first gate insulating film 130 is a single film, but it is only for convenience of explanation and the present disclosure is not limited thereto. The first gate insulating film 130 may include a plurality of films.

The semiconductor device according to some exemplary embodiments may include a negative capacitance (NC) FET using a negative capacitor. For example, the first gate insulating film 130 may include a ferroelectric material film having ferroelectric characteristics and a paraelectric material film having paraelectric characteristics.

The ferroelectric material film may have a negative capacitance, and the paraelectric material film may have a positive capacitance. For example, when two or more capacitors are connected in series with each other and the capacitance of each capacitor has a positive value, a total capacitance decreases as compared with a capacitance of each individual capacitor. On the other hand, when at least one of the capacitances of two or more capacitors connected in series with each other has a negative value, the total capacitance may be greater than an absolute value of each individual capacitance while having a positive value.

When the ferroelectric material film having the negative capacitance and the paraelectric material film having the positive capacitance are connected in series with each other, a total capacitance value of the ferroelectric material film and the paraelectric material film connected in series with each other may increase. A transistor including the ferroelectric material film may have a subthreshold swing (SS) less than 60 mV/decade at room temperature by using the increase in the total capacitance value as a result of including a negative capacitance film and a positive capacitance film in series.

The ferroelectric material film may have the ferroelectric characteristics. The ferroelectric material film may be formed of or include, for example, at least one of hafnium oxide, hafnium zirconium oxide, barium strontium titanium oxide, barium titanium oxide, and lead zirconium titanium oxide. Here, as an example, the hafnium zirconium oxide may be a material obtained by doping hafnium oxide with zirconium (Zr). As another example, the hafnium zirconium oxide may also be a compound of hafnium (Hf), zirconium (Zr), and oxygen (O).

The ferroelectric material film may further include a dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). A type of dopant included in the ferroelectric material film may vary depending on a type of ferroelectric material included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), and yttrium (Y).

When the dopant is aluminum (Al), the ferroelectric material film may include 3 to 8 atomic % (at %) of aluminum. Here, a ratio of the dopant may be a ratio of aluminum to the sum of hafnium and aluminum.

When the dopant is silicon (Si), the ferroelectric material film may include 2 to 10 at % of silicon. When the dopant is yttrium (Y), the ferroelectric material film may include 2 to 10 at % of yttrium. When the dopant is gadolinium (Gd), the ferroelectric material film may contain 1 to 7 at % of gadolinium. When the dopant is zirconium (Zr), the ferroelectric material film may include 50 to 80 at % of zirconium.

The paraelectric material film may have the paraelectric characteristics. The paraelectric material film may include, for example, at least one of silicon oxide and metal oxide having a high dielectric constant. The metal oxide included in the paraelectric material film may include, but is not limited to, for example, at least one of hafnium oxide, zirconium oxide, and aluminum oxide.

The ferroelectric material film and the paraelectric material film may include the same material. The ferroelectric material film may have the ferroelectric characteristics, but the paraelectric material film may not have the ferroelectric characteristics. For example, when the ferroelectric material film and the paraelectric material film include the hafnium oxide, a crystal structure of the hafnium oxide included in the ferroelectric material film is different from a crystal structure of the hafnium oxide included in the paraelectric material film.

The ferroelectric material film may have a thickness that ensures the ferroelectric characteristics. The thickness of the ferroelectric material film may be, for example, 0.5 to 10 nm, but is not limited thereto. Since a critical thickness representing the ferroelectric characteristics may vary for each ferroelectric material, the thickness of the ferroelectric material film may vary depending on the ferroelectric material.

As an example, the first gate insulating film 130 may include one ferroelectric material film. As another example, the first gate insulating film 130 may include a plurality of ferroelectric material films spaced apart from each other. The first gate insulating film 130 may have a stacked film structure in which a plurality of ferroelectric material films and a plurality of paraelectric material films are alternately stacked.

The plurality of first gate capping films 145 may be disposed on upper surfaces of the plurality of first gate stacks GP1 and the plurality of first gate spacers 140, respectively. The plurality of first gate capping films 145 may be formed of or include, for example, at least one of silicon nitride (SiN), silicon oxynitride (SiON), silicon oxide (SiO₂), silicon carbonitride (SiCN), silicon oxycarbonitride (SiOCN), and a combination thereof.

The plurality of second gate structures GS2 may be disposed on the second active pattern AP2. The plurality of second gate structures GS2 may be disposed on the second region R2. The plurality of second gate structures GS2 may be disposed on the NMOS region. The plurality of second gate structures GS2 may intersect the second active pattern AP2. The plurality of second gate structures GS2 may extend in the second direction D2. The plurality of second gate structures GS2 may be spaced apart from each other in the first direction D1.

The plurality of second gate structures GS2 may each include a second gate insulating film 230, a second gate stack GP2, a second gate spacer 240, and a second gate capping film 245.

The second gate stack GP2 may be disposed on the second lower pattern BP2. The second gate stack GP2 may surround the plurality of second sheet patterns SP2.

The second gate stack GP2 may include a second capping pattern 223, a third work function pattern 224, and a second filling pattern 225.

The second capping pattern 223, the third work function pattern 224, and the second filling pattern 225 may be sequentially stacked. For example, the third work function pattern 224 may be disposed on the second capping pattern 223. The second filling pattern 225 may be disposed on the third work function pattern 224.

The second capping pattern 223 may be disposed at the lowest portion of the second gate stack GP2. The second capping pattern 223 may be in contact with the second gate insulating film 230. The second capping pattern 223 may be disposed in a ‘U’ shape along a profile of the second gate insulating film 230. A thickness of the second capping pattern 223 may be constant along the ‘U’ shape, but is not limited thereto.

The second capping pattern 223 may be formed of or include, for example, tungsten (W) or titanium nitride film (TiN). The second capping pattern 223 may be formed of the same material as the first capping pattern 123. The second capping pattern 223 and the first capping pattern 123 may be formed through the same process. The thickness of the second capping pattern 223 may be the same as the thickness of the first capping pattern 123.

The third work function pattern 224 may be disposed on the second capping pattern 223. The third work function pattern 224 may be disposed between the second capping pattern 223 and the second filling pattern 225. The third work function pattern 224 may be disposed in a ‘U’ shape along a profile of the second capping pattern 223. A thickness of the third work function pattern 224 may be constant along the ‘U’ shape, but is not limited thereto.

The third work function pattern 224 may be formed of or include metal carbide with a relatively low work function. In other words, the third work function pattern 224 may include an N-type work function metal. That is, the third work function pattern 224 may be a second N-type work function pattern. For example, the third work function pattern 224 may include at least one of aluminum-doped titanium carbide (TiAlC), aluminum-doped tantalum carbide (TaAlC), aluminum-doped vanadium carbide (VAlC), aluminum and silicon-doped titanium carbide (TiAlSiC), and aluminum and silicon doped tantalum carbide (TaAlSiC). The third work function pattern 224 may be formed of the same material as the second work function pattern 124. The third work function pattern 224 and the second work function pattern 124 may be formed through the same process. A thickness of the third work function pattern 224 may be the same as the thickness of the second work function pattern 124.

The second filling pattern 225 may be disposed on the third work function pattern 224. The second filling pattern 225 may fill a trench remaining after the second capping pattern 223 and the third work function pattern 224 are formed. The second filling pattern 225 may be formed of or include, for example, tungsten (W) or titanium nitride film (TiN). The second filling pattern 225 may be formed of the same material as the first filling pattern 125.

The plurality of second gate stacks GP2 may be disposed on both sides of a second source/drain pattern 250, which will be described later. As an example, the plurality of second gate stacks GP2 disposed on both sides of the second source/drain pattern 250 may be normal gate electrodes used as gates of transistors. As another example, the second gate stack GP2 disposed on one side of the second source/drain pattern 250 is used as the gate of the transistor, but the second gate stack GP2 disposed on the other side of the second source/drain pattern 250 may be a dummy gate electrode.

In some exemplary embodiments, the second gate stack GP2 may include an outer stack GP2_out and an inner stack GP2_in. For example, in FIG. 5, the outer stack GP2_out of the second gate stack GP2 may be disposed on the uppermost sheet pattern of the plurality of second sheet patterns SP2. The inner stack GP2_in of the second gate stack GP2 may be disposed between adjacent second sheet patterns among the plurality of second sheet patterns SP2. In addition, the inner stack GP2_in of the second gate stack GP2 may be disposed between the second sheet pattern SP2 and the second lower pattern BP2.

The outer stack GP2_out of the second gate stack GP2 may be disposed in a trench defined by the second gate insulating film 230 and the second gate capping film 245. The outer stack GP2_out of the second gate stack GP2 may include a second capping pattern 223, a third work function pattern 224, and a second filling pattern 225. The inner stack GP2_in of the second gate stack GP2 may be disposed in a space defined by the second gate insulating film 230. The inner stack GP2_in of the second gate stack GP2 may include only the second capping pattern 223 and the third work function pattern 224.

A plurality of second gate spacers 240 may be disposed on the sidewall of each of the plurality of second gate stacks GP2. The plurality of second gate spacers 240 are not in contact with the plurality of second gate stacks GP2. The second gate insulating film 230 may be disposed between the second gate spacer 240 and the sidewall of the second gate stack GP2.

The second gate insulating film 230 may extend between the second gate stacks GP2 and an upper surface of the field insulating film 105, between the second gate stacks GP2 and an upper surface of the second lower pattern BP2, and between the second gate stacks GP2 and the second sheet patterns SP2. The second gate insulating film 230 may be formed between the second gate stacks GP2 and the second gate spacers 240. In addition, the second gate insulating film 230 may also be formed between the second source/drain pattern 250 and the second gate stacks GP2.

The plurality of second gate capping films 245 may be disposed on upper surfaces of the plurality of second gate stacks GP2 and the plurality of second gate spacers 240, respectively.

Since the descriptions of the materials included in the second gate spacer 240, the second gate insulating film 230, and the second gate capping film 245 may be the same as the descriptions of the materials included in the first gate spacer 140, the first gate insulating film 130, and the first gate capping film 145, respectively, the description thereof will be omitted.

The first source/drain pattern 150 may be disposed on the substrate 100. The first source/drain pattern 150 may be disposed in the first region R1. The first source/drain pattern 150 may be disposed in the PMOS region. The first source/drain pattern 150 may be formed on the first lower pattern BP1. The first source/drain pattern 150 is connected to the first lower pattern BP1. A bottom surface of the first source/drain pattern 150 is in contact with the first lower pattern BP1. The first source/drain pattern 150 may also be connected to the plurality of first sheet patterns SP1. A sidewall of the first source/drain pattern 150 is in contact with the plurality of first sheet patterns SP1.

The first source/drain pattern 150 may be disposed on each side surface of the plurality of first gate stacks GP1. The first source/drain pattern 150 may be disposed between adjacent first gate stacks among the plurality of first gate stacks GP1.

For example, the first source/drain pattern 150 may be disposed on both sides of each of the plurality of first gate stacks GP1. Unlike illustrated, the first source/drain pattern 150 may be disposed on one side of the plurality of first gate stacks GP1 and may not be disposed on the other side of the plurality of first gate stacks GP1.

The first source/drain pattern 150 may include an epitaxial pattern. The first source/drain pattern 150 may be formed of or include a semiconductor material. The first source/drain pattern 150 may be included in a source/drain of a transistor using the first sheet pattern SP1 as a channel region. The first source/drain pattern 150 may include P-type impurities.

The first source/drain pattern 150 may be connected to a channel region of the first active pattern AP1 used as a channel. For example, the first source/drain pattern 150 may be connected to the first sheet pattern SP1.

The second source/drain pattern 250 may be disposed on the substrate 100. The second source/drain pattern 250 may be disposed in the second region R2. The second source/drain pattern 250 may be disposed in the NMOS region. The second source/drain pattern 250 may be formed on the second lower pattern BP2. The second source/drain pattern 250 is connected to the second lower pattern BP2. A bottom surface of the second source/drain pattern 250 is in contact with the second lower pattern BP2. The second source/drain pattern 250 may also be connected to the plurality of second sheet patterns SP2. A sidewall of the second source/drain pattern 250 is in contact with the plurality of second sheet patterns SP2.

The second source/drain pattern 250 may be disposed on each side surface of the plurality of second gate stacks GP2. The second source/drain pattern 250 may be disposed between adjacent second gate stacks among the plurality of second gate stacks GP2.

For example, the second source/drain pattern 250 may be disposed on both sides of each of the plurality of second gate stacks GP2. Unlike illustrated, the second source/drain pattern 250 may be disposed on one side of the plurality of second gate stacks GP2 and may not be disposed on the other side of the plurality of second gate stacks GP2.

The second source/drain pattern 250 may include an epitaxial pattern. The second source/drain pattern 250 may be formed of or include a semiconductor material. The second source/drain pattern 250 may be included in a source/drain of a transistor using the second sheet pattern SP2 as a channel region. The second source/drain pattern 250 may include N-type impurities.

The second source/drain pattern 250 may be connected to a channel region of the second active pattern AP2 used as a channel. For example, the second source/drain pattern 250 may be connected to the second sheet pattern SP2.

The etching stop film 160 may extend along the upper surface of the field insulating film 105, the sidewalls of the plurality of first and second gate spacers 140 and 240, a profile of the first source/drain pattern 150, and a profile of the second source/drain pattern 250. The etching stop film 160 may be disposed on the upper surface of the first source/drain pattern 150, the upper surface of the second source/drain pattern 250, and the sidewalls of the plurality of first and second gate spacers 140 and 240.

In some exemplary embodiments, the etching stop film 160 is not disposed on the sidewalls of the first and second gate capping films 145 and 245. That is, the first and second gate capping films 145 and 245 may be disposed on an upper surface of the etching stop film 160. In addition, a sidewall of the etching stop film 160 may be connected to (e.g., coplanar with) outer sidewalls of the first and second gate capping films 145 and 245. Unlike illustrated, the etching stop film 160 may also be disposed on the sidewalls of the first and second gate capping films 145 and 245.

The etching stop film 160 may include a material having an etching selectivity with respect to a first interlayer insulating film 190 to be described later. The etching stop film 160 may be formed of or include a nitride-based insulating material. For example, the etching stop film 160 may include at least one of silicon nitride (SiN), silicon oxynitride (SiON), silicon oxycarbonitride (SiOCN), silicon boron nitride (SiBN), silicon oxyboron nitride (SiOBN), and a combination thereof.

A first interlayer insulating film 190 may be disposed on the etching stop film 160. The first interlayer insulating film 190 may be formed on the field insulating film 105. The first interlayer insulating film 190 may be disposed on the first source/drain pattern 150 and the second source/drain pattern 250. The first interlayer insulating film 190 may not cover the upper surfaces of the first and second gate capping films 145 and 245. For example, an upper surface of the first interlayer insulating film 190 may be on the same plane as the upper surfaces of the first and second gate capping films 145 and 245.

The first interlayer insulating film 190 may be formed of or include, for example, at least one of silicon oxide, silicon nitride, silicon oxynitride, and a low-k material. The low-k material may include, but is not limited to, for example, fluorinated tetraethylorthosilicate (FTEOS), hydrogen silsesquioxane (HSQ), bis-benzocyclobutene (BCB), tetramethylorthosilicate (TMOS), octamethylcyclotetrasiloxane (OMCTS), hexamethyldisiloxane (HMDS), trimethylsilyl borate (TMSB), diacetoxyditertiarybutosiloxane (DADBS), trimethylsilyl phosphate (TMSP), polytetrafluoroethylene (PTFE), tonen silazene (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or a combination thereof.

The first source/drain contact 170 may be disposed on the first source/drain pattern 150 on the first active pattern AP1. The first source/drain contact 170 may be disposed in the PMOS region. The second source/drain contact 270 may be disposed on the second source/drain pattern 250 on the second active pattern AP2. The second source/drain contact 270 may be disposed in the NMOS region. The first source/drain contact 170 may be connected to the first source/drain pattern 150. The second source/drain contact 270 may be connected to the second source/drain pattern 250.

The first gate contact 180 may be connected to some of the plurality of first gate stacks GP1. The first gate contact 180 may be disposed at a position overlapping with the plurality of first gate stacks GP1 when viewed in plan view. The second gate contact 280 may be connected to some of the plurality of second gate stacks GP2. The second gate contact 280 may be disposed at a position overlapping with the plurality of second gate stacks GP2 when viewed in plan view.

The first source/drain contact 170 may penetrate through the etching stop film 160 and be connected to the first source/drain pattern 150. The first source/drain contact 170 may be disposed on the first source/drain pattern 150.

The first source/drain contact 170 may be disposed in the first interlayer insulating film 190. The first source/drain contact 170 may be surrounded by the first interlayer insulating film 190.

A first contact silicide film 155 may be disposed between the first source/drain contact 170 and the first source/drain pattern 150. It is illustrated that the first contact silicide film 155 is formed along a profile of an interface between the first source/drain pattern 150 and the first source/drain contact 170, but the present disclosure is not limited thereto. The first contact silicide film 155 may be formed of or include, for example, a metal silicide material.

An upper surface of the first source/drain contact 170 may be on the same plane as the upper surface of the first gate contact 180. The upper surface of the first source/drain contact 170 may be on the same plane as the upper surface of the first interlayer insulating film 190 and the upper surface of the first gate capping film 145.

In some exemplary embodiments, the first source/drain contact 170 may include a first source/drain barrier film 170BL and a first source/drain filling film 170FL on the first source/drain barrier film 170BL.

It is illustrated that a bottom surface of the first source/drain contact 170 has a flat shape, but the present disclosure is not limited thereto. Unlike illustrated, the bottom surface of the first source/drain contact 170 may have a wavy shape.

The first source/drain barrier film 170BL may be formed of or include, for example, at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and a two-dimensional (2D) material. In the semiconductor device according to some exemplary embodiments, the 2D material may be a metallic material and/or a semiconductor material. The 2D material may include, but is not limited to, a two-dimensional allotrope or a two-dimensional compound, and may include, for example, at least one of graphene, molybdenum disulfide (MoS₂), molybdenum diselenide (MoSe₂), tungsten diselenide (WSe₂), and tungsten disulfide (WS₂). That is, since the above-described 2D material is only listed as an example, the 2D material that may be included in the semiconductor device of the present disclosure is not limited by the above-described material.

The first source/drain filling film 170FL may be formed of or include, for example, at least one of aluminum (Al), tungsten (W), cobalt (Co), ruthenium (Ru), silver (Ag), gold (Au), manganese (Mn), and molybdenum (Mo).

It is illustrated that the first source/drain contact 170 includes a plurality of conductive films, but the present disclosure is not limited thereto. Unlike illustrated, the first source/drain contact 170 may be a single film.

The second source/drain contact 270 may penetrate through the etching stop film 160 and be connected to the second source/drain pattern 250. The second source/drain contact 270 may be disposed on the second source/drain pattern 250.

The second source/drain contact 270 may be disposed in the first interlayer insulating film 190. The second source/drain contact 270 may be surrounded by the first interlayer insulating film 190.

A second contact silicide film 255 may be disposed between the second source/drain contact 270 and the second source/drain pattern 250. It is illustrated that the second contact silicide film 255 is formed along a profile of an interface between the second source/drain pattern 250 and the second source/drain contact 270, but the present disclosure is not limited thereto. The second contact silicide film 255 may be formed of or include, for example, a metal silicide material.

An upper surface of the second source/drain contact 270 may be on the same plane as the upper surface of the second gate contact 280. The upper surface of the second source/drain contact 270 may be on the same plane as the upper surface of the first interlayer insulating film 190 and the upper surface of the second gate capping film 245.

In some exemplary embodiments, the second source/drain contact 270 may include a second source/drain barrier film 270BL and a second source/drain filling film 270FL on the second source/drain barrier film 270BL.

It is illustrated that a bottom surface of the second source/drain contact 270 has a flat shape, but the present disclosure is not limited thereto. Unlike illustrated, the bottom surface of the second source/drain contact 270 may have a wavy shape.

The material included in the second source/drain barrier film 270BL may be the same as the material included in the first source/drain barrier film 170BL. The material included in the second source/drain filling film 270FL may be the same as the material included in the first source/drain filling film 170FL.

It is illustrated that the second source/drain contact 270 includes a plurality of conductive films, but the present disclosure is not limited thereto. Unlike illustrated, the second source/drain contact 270 may be a single film.

The first gate contact 180 may be disposed on the first gate stack GP1. The first gate contact 180 may be disposed on the PMOS region. The first gate contact 180 may penetrate through the first gate capping film 145 and be connected to the first gate stack GP1.

As an example, an upper surface of the first gate contact 180 may be on the same plane as the upper surface of the first gate capping film 145. Unlike illustrated, as another example, the upper surface of the first gate contact 180 may protrude above the upper surface of the first gate capping film 145.

The first gate contact 180 may include a first gate barrier film 180BL and a first gate filling film 180FL on the first gate barrier film 180BL. The description of the materials included in the first gate barrier film 180BL and the first gate filling film 180FL may be the same as the description of the first source/drain barrier film 170BL and the first source/drain filling film 170FL.

The second gate contact 280 may be disposed on the second gate stack GP2. The second gate contact 280 may be disposed on the NMOS region. The second gate contact 280 may penetrate through the second gate capping film 245 and be connected to the second gate stack GP2.

As an example, an upper surface of the second gate contact 280 may be on the same plane as the upper surface of the second gate capping film 245. Unlike illustrated, as another example, the upper surface of the second gate contact 280 may protrude above the upper surface of the second gate capping film 245.

The second gate contact 280 may include a second gate barrier film 280BL and a second gate filling film 280FL on the second gate barrier film 280BL. The description of the materials included in the second gate barrier film 280BL and the second gate filling film 280FL may be the same as the description of the first source/drain barrier film 170BL and the first source/drain filling film 170FL.

The semiconductor device according to some exemplary embodiments may further include an upper stop film 191, a second interlayer insulating film 192, a first via plug 195, and a second via plug 295.

The upper stop film 191 may be disposed on the first interlayer insulating film 190, the first gate capping film 145, the second gate capping film 245, the first source/drain contact 170, the second source/drain contact 270, the first gate contact 180, and the second gate contact 280. The second interlayer insulating film 192 may be disposed on the upper stop film 191.

The upper stop film 191 may include a material having an etching selectivity with respect to the second interlayer insulating film 192. The upper stop film 191 may be formed of or include, for example, at least one of silicon nitride (SiN), silicon oxynitride (SiON), silicon oxycarbonitride (SiOCN), silicon boron nitride (SiBN), silicon oxyboron nitride (SiOBN), silicon oxycarbide (SiOC), aluminum oxide (AlO), aluminum nitride (AlN), aluminum oxycarbide (AlOC), and a combination thereof. It is illustrated that the upper stop film 191 is a single film, but the present disclosure is not limited thereto. Unlike illustrated, the upper stop film 191 may not be formed. The second interlayer insulating film 192 may be formed of or include, for example, at least one of silicon oxide, silicon nitride, silicon carbonitride, silicon oxynitride, and a low-k material.

The first via plug 195 may be disposed in the second interlayer insulating film 192. The first via plug 195 may pass through the upper stop film 191 and be directly connected to the first source/drain contact 170. A portion of the first via plug 195 may completely cover the upper surface of the first source/drain contact 170.

The first via plug 195 may include a first via barrier film 195BL and a first via filling film 195FL. The first via barrier film 195BL may extend along a sidewall and a bottom surface of the first via filling film 195FL. The first via barrier film 195BL may be formed of or include, for example, at least one of tantalum (Ta), tantalum nitride (TaN), titanium (Ti), titanium nitride (TiN), titanium silicon nitride (TiSiN), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and a two-dimensional (2D) material. The first via filling film 195FL may be formed of or include, for example, at least one of aluminum (Al), tungsten (W), cobalt (Co), ruthenium (Ru), copper (Cu), silver (Ag), gold (Au), manganese (Mn), and molybdenum (Mo).

The second via plug 295 may be disposed in the second interlayer insulating film 192. The second via plug 295 may pass through the upper stop film 191 and be connected to the second source/drain contact 270. A portion of the second via plug 295 may completely cover the upper surface of the second source/drain contact 270.

The second via plug 295 may include a second via barrier film 295BL and a second via filling film 295FL. The second via barrier film 295BL may extend along a sidewall and a bottom surface of the second via filling film 295FL. The material included in the second via barrier film 295BL may be the same as the material included in the first via barrier film 195BL. The material included in the second via filling film 295FL may be the same as the material included in the first via filling film 195FL.

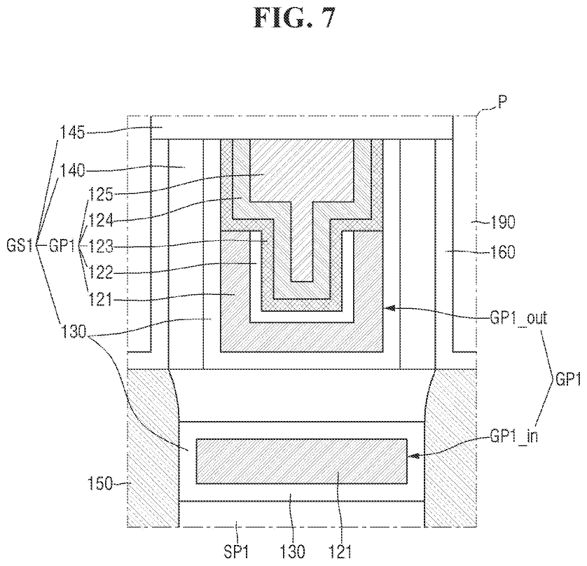

Hereinafter, a semiconductor device according to some other exemplary embodiments will be described with reference to FIGS. 7 to 9. For convenience of explanation, points different from those described with reference to FIGS. 1 to 5 will be mainly described.

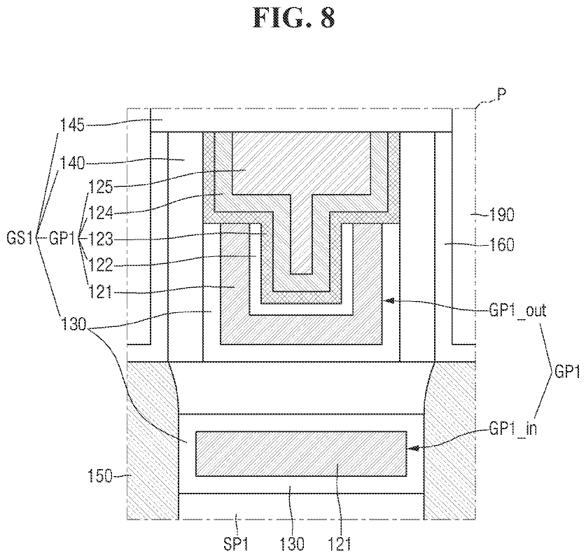

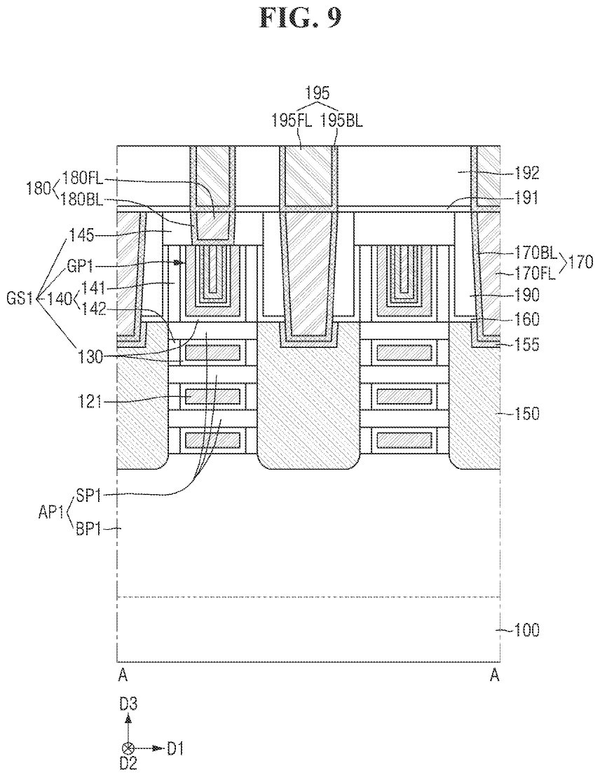

FIGS. 7 to 9 are views for describing a semiconductor device according to some other exemplary embodiments of the present disclosure. For reference, FIGS. 7 and 8 are views for describing a first gate stack according to some other exemplary embodiments of the present disclosure, and FIG. 9 is an exemplary cross-sectional view taken along line A-A of FIG. 1.

First, referring to FIG. 7, the first work function pattern 121 and the diffusion prevention pattern 122 may not extend to the uppermost portion of the first gate insulating film 130. In this case, a portion of the first capping pattern 123 may be in contact with the first gate insulating film 130. The first capping pattern 123 may be in contact with upper surfaces of the first work function pattern 121 and the diffusion prevention pattern 122.

This may be because when removing the first work function pattern 121 and the diffusion prevention pattern 122 from the NMOS region, some of the first work function pattern 121 and the diffusion prevention pattern 122 are removed from the PMOS region.

Referring to FIG. 8, the first gate insulating film 130, the first work function pattern 121, and the diffusion prevention pattern 122 may not extend to the first gate capping film 145. The first gate insulating film 130, the first work function pattern 121, and the diffusion prevention pattern 122 may not extend to the uppermost portion of the first gate spacer 140. In this case, a portion of the first capping pattern 123 may be in contact with the first gate spacer 140. The first capping pattern 123 may be in contact with upper surfaces of the first gate insulating film 130, the first work function pattern 121, and the diffusion prevention pattern 122.

Referring to FIG. 9, the first gate spacer 140 may include a first inner spacer 141 and a first outer spacer 142. The first outer spacer 142 may be disposed between the first lower pattern BP1 and the first sheet pattern SP1 and between the first sheet patterns SP1 adjacent to each other. Although not illustrated, even in the NMOS region, the second gate spacer 240 may include a second inner spacer and a second outer spacer. The second outer spacer may be disposed between the second lower pattern BP2 and the second sheet pattern SP2 and between the second sheet patterns SP2 adjacent to each other.

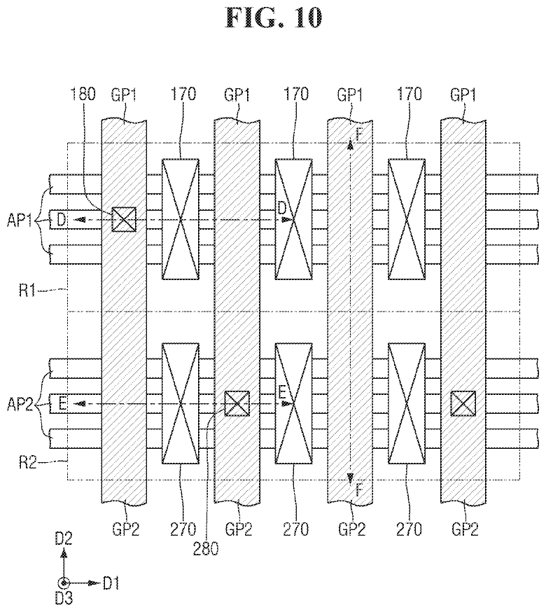

Hereinafter, a semiconductor device according to some other exemplary embodiments of the present disclosure will be described with reference to FIGS. 10 to 13.

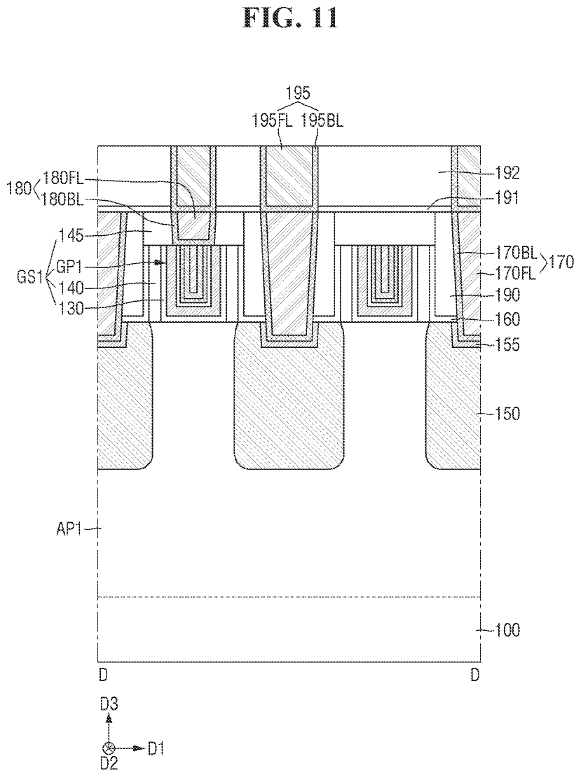

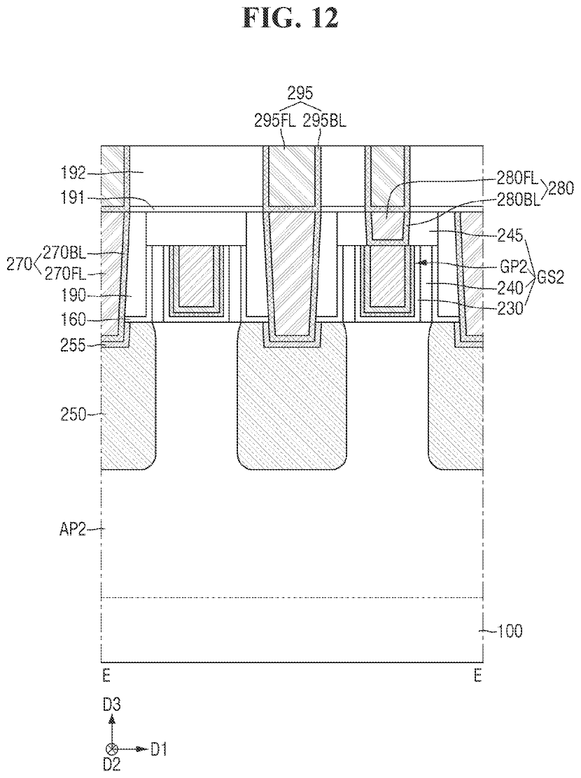

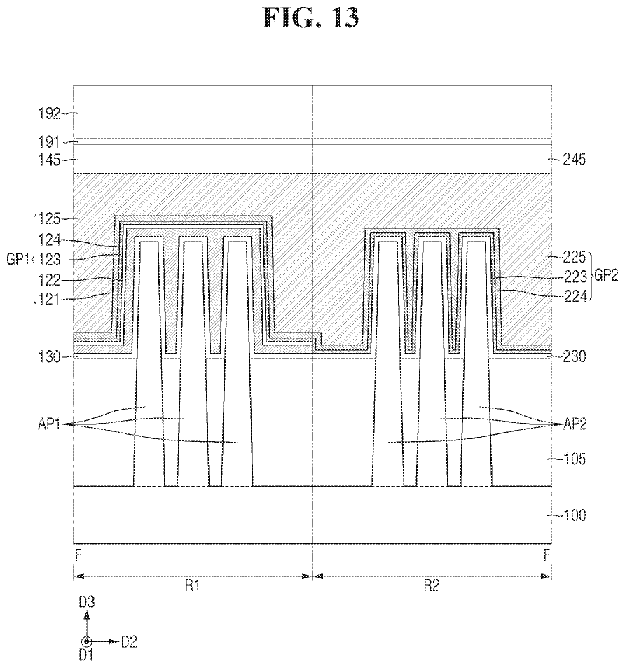

FIG. 10 is an exemplary plan view for describing a semiconductor device according to some other exemplary embodiments of the present disclosure. FIG. 11 is an exemplary cross-sectional view taken along line D-D of FIG. 10. FIG. 12 is an exemplary cross-sectional view taken along line E-E of FIG. 10. FIG. 13 is an exemplary cross-sectional view taken along line F-F of FIG. 10.

Referring to FIGS. 10 to 13, the semiconductor device according to some exemplary embodiments may be a fin-type transistor (FinFET). The semiconductor device according to some exemplary embodiments may not include sheet patterns.

In the semiconductor device according to some exemplary embodiments, each of the first active pattern AP1 and the second active pattern AP2 may be a fin-type pattern. The first active pattern AP1 and the second active pattern AP2 may each extend from the substrate 100 in the third direction D3. The first active pattern AP1 and the second active pattern AP2 may each extend in the first direction D1.

The number of first active patterns AP1 may be one or more. The first active patterns AP1 may be spaced apart from each other in the second direction D2. It is illustrated that the number of first active patterns AP1 is three, but the technical spirit of the present disclosure is not limited thereto.

Likewise, the number of second active patterns AP2 may be one or more. The second active patterns AP2 may be spaced apart from each other in the second direction D2. It is illustrated that the number of second active patterns AP2 is three, but the technical spirit of the present disclosure is not limited thereto.

A portion of the first active pattern AP1 interposed between the first source/drain patterns 150 may function as a channel for the fin-type transistor. A portion of the second active pattern AP2 interposed between the second source/drain patterns 250 may function as a channel for the fin-type transistor. A portion of the first active pattern AP1 interposed between the first source/drain patterns 150 may be covered by the first gate stack GP1. A portion of the second active pattern AP2 interposed between the second source/drain patterns 250 may be covered by the second gate stack GP2.

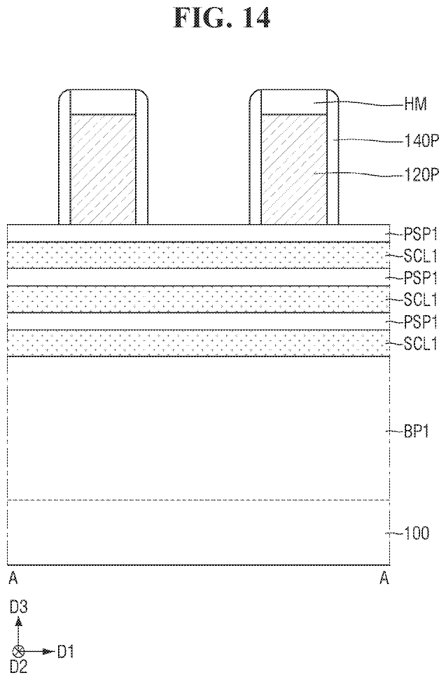

Hereinafter, a method for fabricating a semiconductor device according to some exemplary embodiments of the present disclosure will be described with reference to FIGS. 14 to 27.

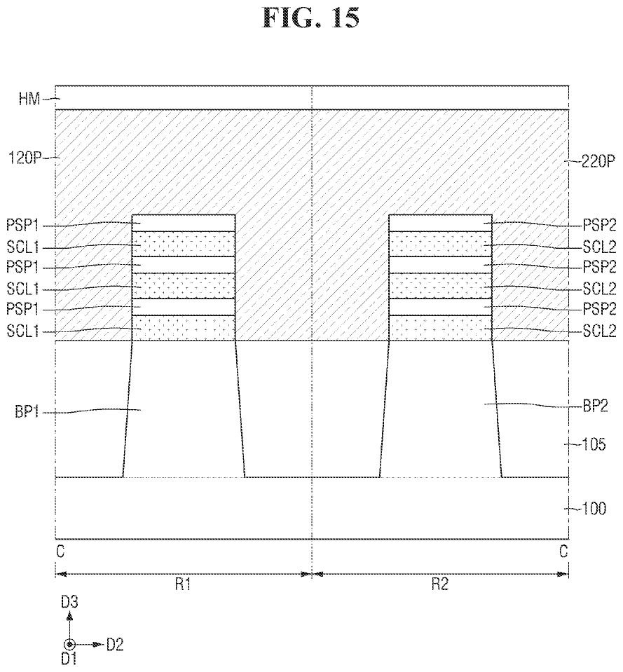

FIGS. 14 to 27 are intermediate step views for describing a method for fabricating a semiconductor device according to some exemplary embodiments of the present disclosure. For reference, FIGS. 14, 16, 17, 19, 21, 25, and 26 are intermediate step views for describing a method for fabricating the semiconductor device having the cross section of FIG. 2, and FIGS. 15, 18, 20, 22, 23, 24, and 27 may be intermediate step views for describing a method of fabricating a semiconductor device having the cross-section of FIG. 6.

First, referring to FIGS. 14 and 15, a substrate 100 may be provided. The substrate 100 may include a first region R1 and a second region R2. The first region R1 may be a PMOS region and the second region R2 may be an NMOS region. A first lower pattern BP1 and a second lower pattern BP2 may be formed on the substrate 100. The first lower pattern BP1 may be formed on the first region R1, and the second lower pattern BP2 may be formed on the second region R2. That is, the first lower pattern BP1 may be formed on the PMOS region, and the second lower pattern BP2 may be formed on the NMOS region.

A field insulating film 105 may be formed on sidewalls of the first lower pattern BP1 and the second lower pattern BP2.

A first sacrificial film SCL1 and a pre-first sheet pattern PSP1 may be alternately stacked on the first lower pattern BP1. For example, the first sacrificial film SCL1 may be first formed on the first lower pattern BP1. The pre-first sheet pattern PSP1 may be formed on the first sacrificial film SCL1. The first sacrificial film SCL1 may be formed again on the pre-first sheet pattern PSP1. It is illustrated in FIGS. 14 and 15 that three first sacrificial films SCL1 and three pre-first sheet patterns PSP1 are alternately stacked, but the technical spirit of the present disclosure is not limited thereto.

A second sacrificial film SCL2 and a pre-second sheet pattern PSP2 may be alternately stacked on the second lower pattern BP2. For example, the second sacrificial film SCL2 may be first formed on the second lower pattern BP2. The pre-second sheet pattern PSP2 may be formed on the second sacrificial film SCL2. The second sacrificial film SCL2 may be formed again on the pre-second sheet pattern PSP2. It is illustrated in FIGS. 14 and 15 that three second sacrificial films SCL2 and three pre-second sheet patterns PSP2 are alternately stacked, but the technical spirit of the present disclosure is not limited thereto.

The first and second sacrificial films SCL1 and SCL2 may each be formed of or include, for example, silicon-germanium (SiGe) or germanium (Ge). The pre-first sheet pattern PSP1 and the pre-second sheet pattern PSP2 may each be formed of or include silicon (Si).

Next, a dummy first gate stack 120P, a pre-first gate spacer 140P, and a hard mask film HM may be formed on the pre-first sheet pattern PSP1 disposed on the uppermost portion. The dummy first gate stack 120P may be formed in the PMOS region. The dummy first gate stack 120P and the hard mask film HM may be formed between the pair of pre-first gate spacers 140P. The hard mask film HM may be formed on the dummy first gate stack 120P.

The dummy first gate stack 120P may be formed of or include, for example, polysilicon, but is not limited thereto. The hard mask film HM may be formed of or include, for example, silicon nitride, but is not limited thereto. The pre-first gate spacer 140P may be formed of or include silicon oxide, but is not limited thereto.

In FIG. 15, the dummy first gate stack 120P may be formed on the field insulating film 105. The dummy first gate stack 120P may cover the pre-first sheet pattern PSP1 and the first sacrificial film SCL1.

In addition, a dummy second gate stack 220P may be formed. The dummy second gate stack 220P may be formed in the NMOS region. The dummy second gate stack 220P may be formed of or include, for example, polysilicon, but is not limited thereto. The hard mask film HM may be formed on the dummy second gate stack 220P.

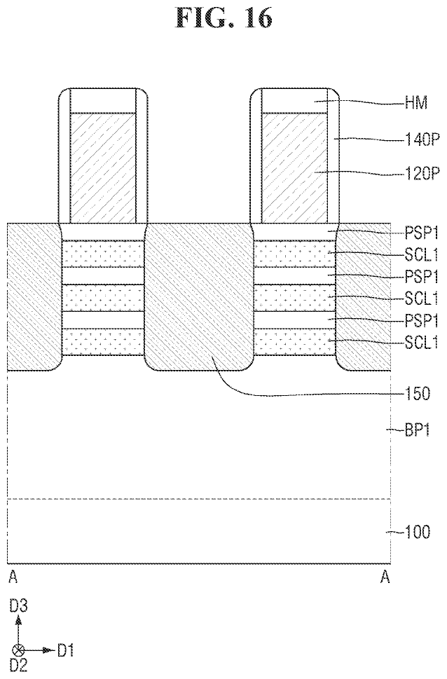

Referring to FIG. 16, the pre-first sheet pattern PSP1 and the first sacrificial film SCL1 may be etched using the hard mask film HM and the pre-first gate spacer 140P as an etch mask. A first source/drain pattern 150 may be formed in a recess formed by etching the pre-first sheet pattern PSP1 and the first sacrificial film SCL1.

Although not illustrated, in the second region R2, the pre-second sheet pattern PSP2 and the second sacrificial film SCL2 may be etched using the hard mask film HM and the dummy second gate spacer as an etch mask. A second source/drain pattern 250 may be formed in a recess formed by etching the pre-second sheet pattern PSP2 and the second sacrificial film SCL2.

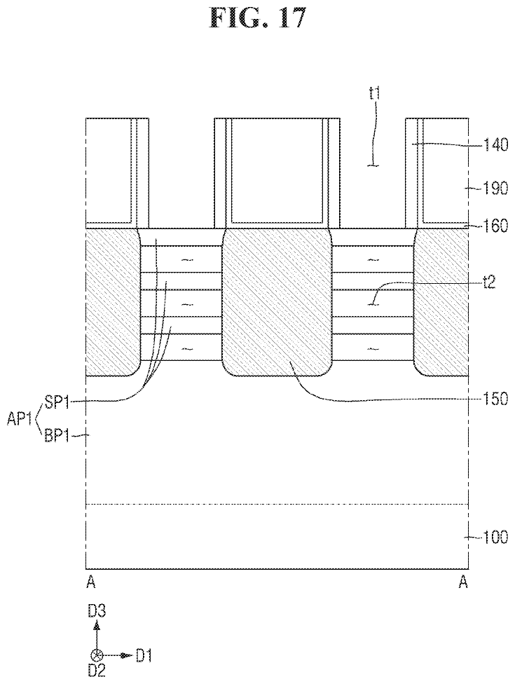

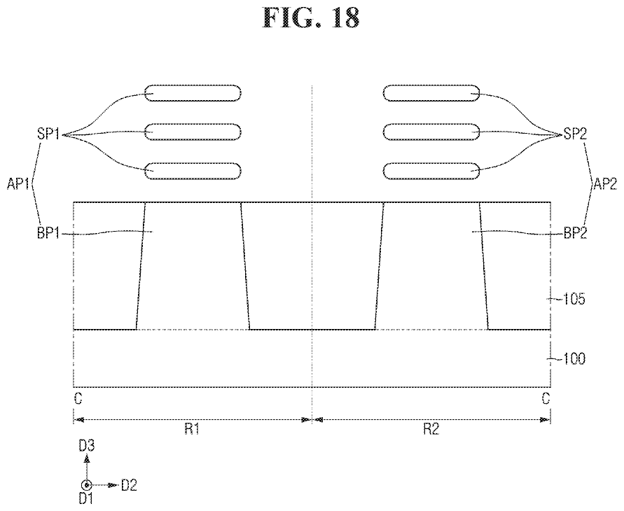

Referring to FIGS. 17 and 18, an etching stop film 160 and a first interlayer insulating film 190 may be formed on the first source/drain pattern 150. Next, the first interlayer insulating film 190 may be removed through a planarization process. The planarization process may be performed until the hard mask film HM is removed. In this case, the dummy first gate stack 120P and the dummy second gate stack 220P may be exposed. In addition, as the pre-first gate spacer 140P is removed, the first gate spacer 140 may be formed.

Next, the dummy first gate stack 120P, the dummy second gate stack 220P, the first sacrificial film SCL1, and the second sacrificial film SCL2 may be removed.

In FIG. 17, a first trench t1 may be formed by removing the dummy first gate stack 120P. The first trench t1 may be defined by the uppermost surface of the first sheet pattern SP1 and the first gate spacer 140. A second trench t2 may be formed by removing the first sacrificial film SCL1. The second trench t2 may be defined by the first sheet patterns SP1 and the first lower pattern BP1.

First, the dummy first gate stack 120P and the dummy second gate stack 220P may be removed. As the dummy first gate stack 120P and the dummy second gate stack 220P are removed, the first sacrificial film SCL1 and the second sacrificial film SCL2 may be exposed. The first sacrificial film SCL1 and the second sacrificial film SCL2 that are exposed may be selectively removed. While the first sacrificial film SCL1 and the second sacrificial film SCL2 are removed, the first sheet pattern SP1 and the second sheet pattern SP2 may be formed. For example, the first sheet pattern SP1 and the second sheet pattern SP2 may be formed by the removal of the first sacrificial film SCL1 and the second sacrificial film SCL2, respectively.

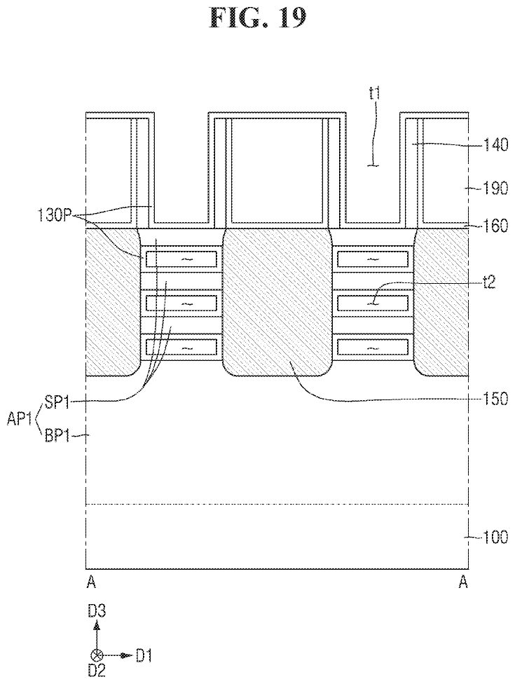

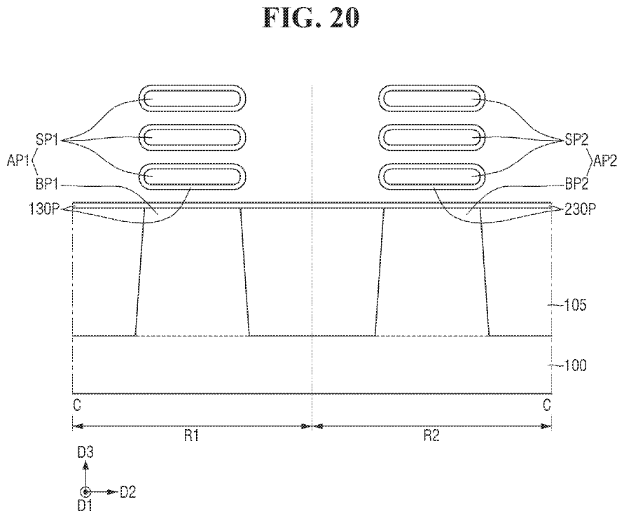

Referring to FIGS. 19 and 20, a pre-first gate insulating film 130P may be formed along an upper surface of the field insulating film 105, an upper surface of the first lower pattern BP1, and a perimeter of the first sheet patterns SP1. A pre-second gate insulating film 230P may be formed along the upper surface of the field insulating film 105, an upper surface of the second lower pattern BP2, and a perimeter of the second sheet pattern SP2.

In FIG. 19, the pre-first gate insulating film 130P may extend along sidewalls and a bottom surface of the first trench t1 and the upper surface of the first interlayer insulating film 190. In addition, the pre-first gate insulating film 130P may be formed along sidewalls of the second trench t2.

The pre-first gate insulating film 130P may be formed on the first region R1, and the pre-second gate insulating film 230P may be formed on the second region R2. The pre-first gate insulating film 130P and the pre-second gate insulating film 230P may be formed through the same process.

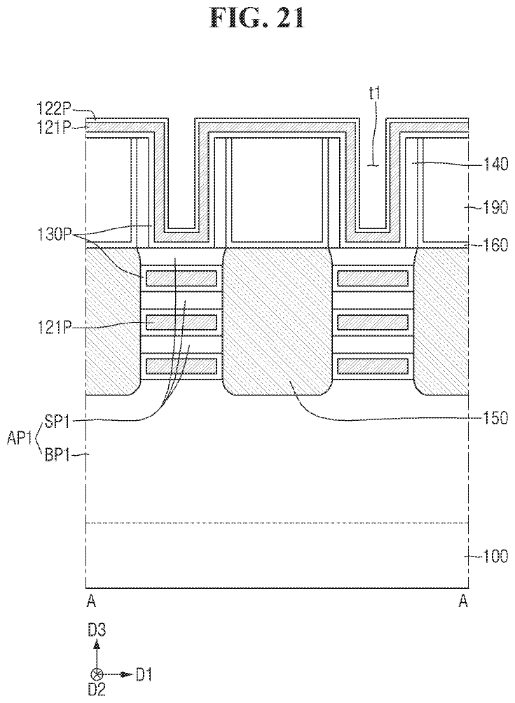

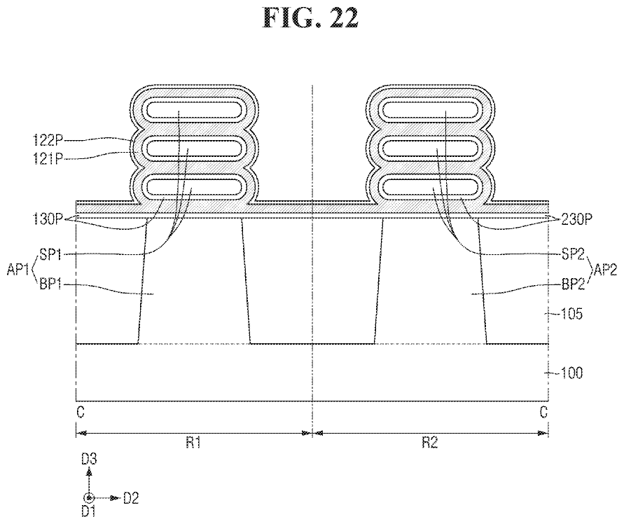

Referring to FIGS. 21 and 22, a pre-first work function pattern 121P may be formed on the first region R1 and the second region R2. The pre-first work function pattern 121P may be formed on the pre-first gate insulating film 130P and the pre-second gate insulating film 230P. A pre-diffusion prevention pattern 122P may be formed on the pre-first work function pattern 121P.

The pre-first work function pattern 121P may include a P-type work function metal. For example, the pre-first work function pattern 121P may include at least one of a titanium nitride film (TiN), a tantalum nitride film (TaN), a titanium oxynitride film (TiON), a titanium silicon nitride film (TiSiN), a titanium aluminum nitride film (TiAlN), a tungsten carbon nitride film (WCN), and a molybdenum nitride film (MoN).

The pre-diffusion prevention pattern 122P may include silicon (Si). A thickness of the pre-diffusion prevention pattern 122P may be 3 Å or more and 10 Å or less.

In FIG. 21, the pre-first work function pattern 121P may fill the second trench t2. Therefore, the pre-diffusion prevention pattern 122P is not formed in the second trench t2.

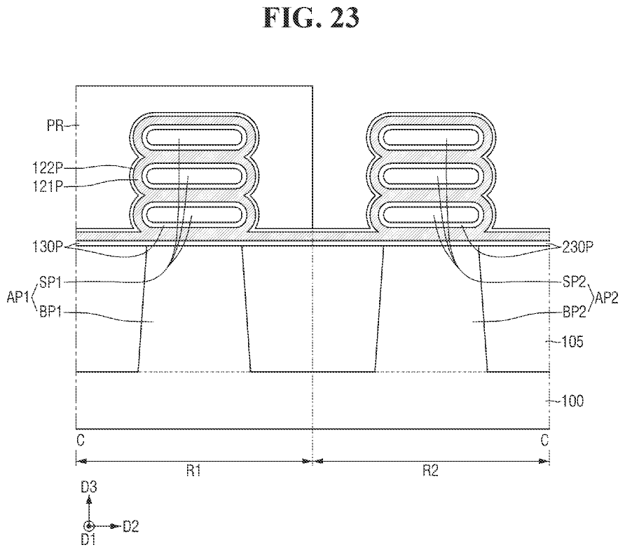

Referring to FIG. 23, a photoresist PR may be formed on the substrate 100 in the first region R1. The photoresist PR may cover the first region R1. The photoresist PR may expose the second region R2.

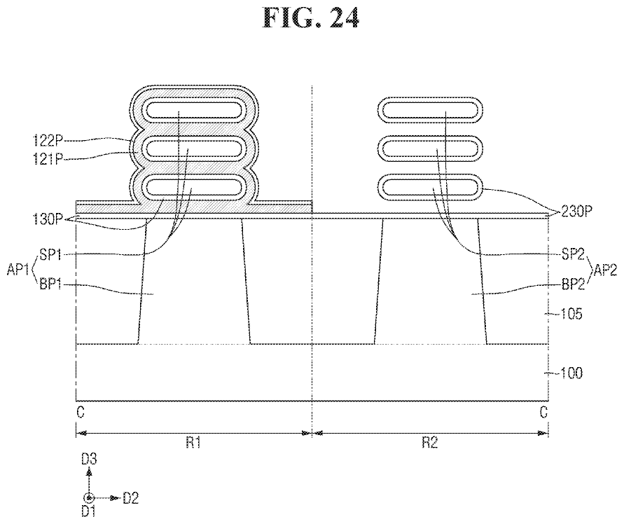

Referring to FIG. 24, the pre-first work function pattern 121P and the pre-diffusion prevention pattern 122P on the second region R2 may be removed by using the photoresist PR as an etch mask. The pre-second gate insulating film 230P may be exposed by removing the pre-first work function pattern 121P and the pre-diffusion prevention pattern 122P.

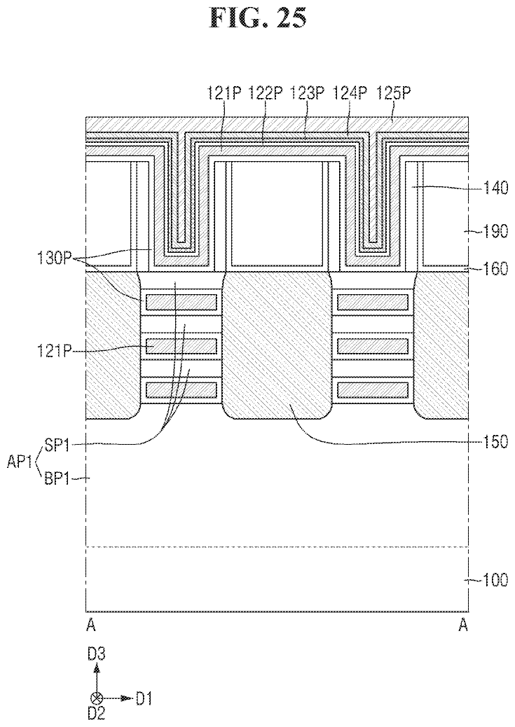

Referring to FIG. 25, in the first region R1, a pre-first capping pattern 123P, a pre-second work function pattern 124P, and a pre-first filling pattern 125P may be sequentially formed on the pre-diffusion prevention pattern 122P.

Although not illustrated, in the second region R2, a pre-second capping pattern, a pre-third work function pattern, and a pre-second filling pattern may be sequentially formed on the pre-second gate insulating film 230P. The pre-second capping pattern may be formed through the same process as the pre-first capping pattern 123P. The pre-third work function pattern may be formed through the same process as the pre-second work function pattern 124P. The pre-second filling pattern may be formed through the same process as the pre-first filling pattern 125P.

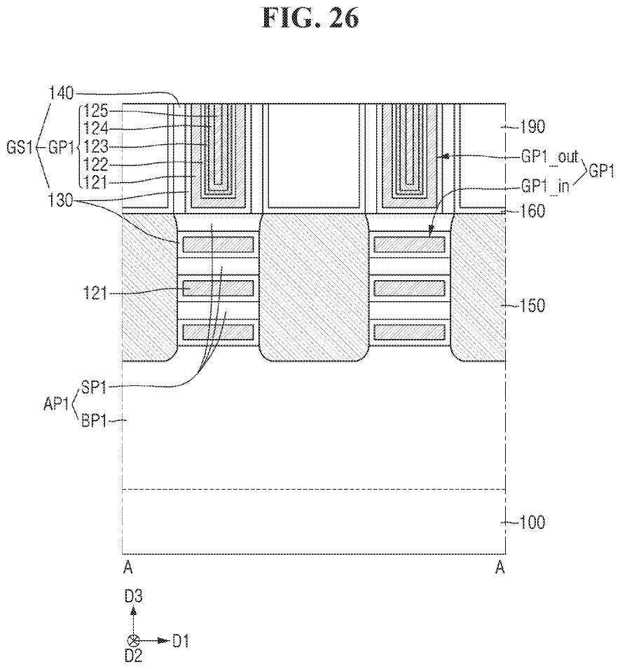

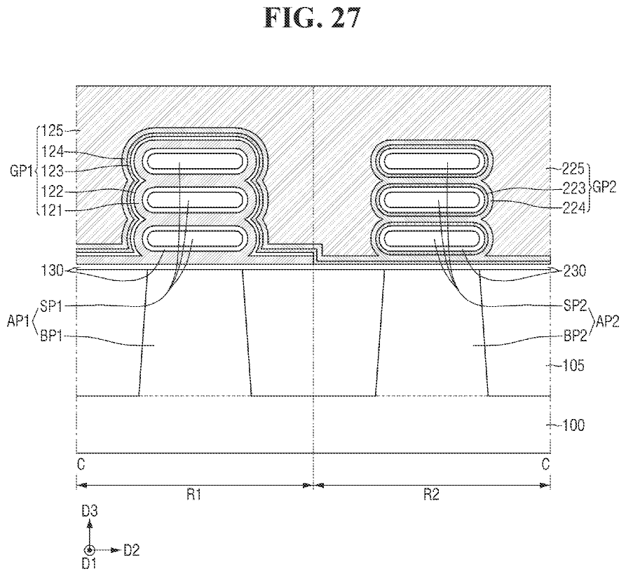

Referring to FIGS. 26 and 27, in the first region R1, a first gate stack GP1 may be formed by patterning the pre-first work function pattern 121P, the pre-diffusion prevention pattern 122P, the pre-first capping pattern 123P, the pre-second work function pattern 124P, and the pre-first filling pattern 125P.

The first gate stack GP1 may include a first work function pattern 121, a diffusion prevention pattern 122, a first capping pattern 123, a second work function pattern 124, and a first filling pattern 125.

Likewise, in the second region R2, a second gate stack GP2 may be formed by patterning the pre-second capping pattern 223P, the pre-third work function pattern 224P, and the pre-second filling pattern 225P.

The second gate stack GP2 may include a second capping pattern 223, a third work function pattern 224, and a second filling pattern 225.

In the first region R1, a concentration of aluminum included in the first work function pattern 121 is lower than a concentration of aluminum included in the second work function pattern 124. In this case, as the diffusion prevention pattern 122 is formed between the first work function pattern 121 and the second work function pattern 124, it is possible to prevent aluminum from diffusing from the second work function pattern 124 to the first work function pattern 121. Accordingly, a semiconductor device having improved reliability may be fabricated.

The exemplary embodiments of the present disclosure have been described above with reference to the accompanying drawings, but the present disclosure may be implemented in various different forms, and those skilled in the art to which the present disclosure pertains may understand that the present disclosure may be implemented in other specific forms without changing the technical spirit or essential features of the present disclosure. Therefore, it should be understood that the exemplary embodiments described above are illustrative in all aspects and not restrictive.

What is claimed is:

1. A semiconductor device comprising:
an active pattern extending in a first direction on a substrate;
a gate stack extending in a second direction intersecting the first direction on the active pattern; and
a source/drain pattern on at least one side of the gate stack,
wherein the gate stack includes:
a first work function pattern;
a second work function pattern on the first work function pattern; and
a diffusion prevention pattern between the first work function pattern and the second work function pattern, and
wherein a concentration of aluminum in the second work function pattern is greater than a concentration of aluminum in the first work function pattern.

2. The semiconductor device of claim 1, wherein the diffusion prevention pattern includes silicon (Si).

3. The semiconductor device of claim 1, wherein a thickness of the diffusion prevention pattern is 3 Å or more and 10 Å or less.

4. The semiconductor device of claim 1, wherein the source/drain pattern includes P-type impurities.

5. The semiconductor device of claim 1, wherein the first work function pattern does not include aluminum (Al).

6. The semiconductor device of claim 1, wherein the gate stack includes a capping pattern between the diffusion prevention pattern and the second work function pattern.

7. The semiconductor device of claim 1, wherein the active pattern includes:
a lower pattern extending in the first direction, and
a plurality of sheet patterns spaced apart from each other in a third direction on the lower pattern, and
wherein the third direction intersects the first direction and the second direction.

8. A semiconductor device comprising:
a lower pattern extending in a first direction on a substrate;
a plurality of sheet patterns spaced apart from each other in a third direction on the lower pattern;
a gate stack extending in a second direction on the lower pattern and surrounding the plurality of sheet patterns; and
a source/drain pattern on at least one side of the gate stack, the source/drain pattern being connected to the plurality of sheet patterns,
wherein the gate stack includes an inner stack between adjacent sheet patterns among the plurality of sheet patterns and between the plurality of sheet patterns and the lower pattern, and an outer stack on the plurality of sheet patterns,
wherein the outer stack of the gate stack includes:
a first work function pattern;
a second work function pattern on the first work function pattern; and
a diffusion prevention pattern between the first work function pattern and the second work function pattern, the diffusion prevention pattern being formed of silicon (Si)
wherein the inner stack of the gate stack includes only the first work function pattern without including the second work function pattern and without including the diffusion prevention pattern,
wherein a concentration of aluminum in the second work function pattern is greater than a concentration of aluminum in the first work function pattern, and
wherein the first direction, the second direction, and the third direction intersect each other.

9. The semiconductor device of claim 8, wherein a concentration of aluminum in the first work function pattern of the inner stack is the same as a concentration of aluminum in the first work function pattern of the outer stack.

10. The semiconductor device of claim 8, wherein a thickness of the diffusion prevention pattern is 3 Å or more and 10 Å or less.

11. The semiconductor device of claim 8, wherein the source/drain pattern includes P-type impurities.

12. The semiconductor device of claim 8, wherein the first work function pattern includes at least one of a titanium nitride film (TiN), a tantalum nitride film (TaN), a titanium oxynitride film (TiON), a titanium silicon nitride film (TiSiN), a titanium aluminum nitride film (TiAlN), a tungsten carbon nitride film (WCN), and a molybdenum nitride film (MoN).

13. The semiconductor device of claim 12, wherein the second work function pattern includes at least one of aluminum-doped titanium carbide (TiAlC), aluminum-doped tantalum carbide (TaAlC), aluminum-doped vanadium carbide (VAlC), aluminum and silicon-doped titanium carbide (TiAlSiC), and aluminum and silicon doped tantalum carbide (TaAlSiC).

14. The semiconductor device of claim 8, wherein the diffusion prevention pattern has a thickness that prevents aluminum in the second work function pattern from diffusing into the first work function pattern.

15. A semiconductor device comprising:
a substrate including a PMOS region and an NMOS region;
a first lower pattern, on the PMOS region of the substrate, extending in a first direction;
a plurality of first sheet patterns, on the first lower pattern, spaced apart from each other in a third direction;
a first gate structure, on the PMOS region, extending in a second direction of the substrate and surrounding the plurality of first sheet patterns;
a first source/drain pattern on at least one side of the first gate structure, the first source/drain pattern being connected to the plurality of first sheet patterns and including P-type impurities;
a second lower pattern, on the NMOS region of the substrate, extending in the first direction;
a plurality of second sheet patterns, on the second lower pattern, spaced apart from each other in the third direction;
a second gate structure, on the NMOS region, extending in the second direction and surrounding the plurality of second sheet patterns; and
a second source/drain pattern on at least one side of the second gate structure, the second source/drain pattern being connected to the plurality of second sheet patterns and including N-type impurities,
wherein the first gate structure includes a first gate insulating film, a P-type work function pattern in contact with the first gate insulating film, a first N-type work function pattern on the P-type work function pattern, a diffusion prevention pattern between the P-type work function pattern and the first N-type work function pattern, and a first capping pattern between the first N-type work function pattern and the diffusion prevention pattern,
wherein the second gate structure includes a second gate insulating film, a second capping pattern in contact with the second gate insulating film, and a second N-type work function pattern on the second capping pattern,
wherein the first N-type work function pattern and the second N-type work function pattern are formed of the same material,
wherein a concentration of aluminum in the P-type work function pattern is greater than a concentration of aluminum in the first N-type work function pattern, and
wherein the first direction, the second direction, and the third direction intersect each other.

16. The semiconductor device of claim 15, wherein the diffusion prevention pattern includes silicon (Si).

17. The semiconductor device of claim 15, wherein the diffusion prevention pattern is in contact with the P-type work function pattern.

18. The semiconductor device of claim 15, wherein the first capping pattern is in contact with each of the P-type work function pattern and the first N-type work function pattern.

19. The semiconductor device of claim 15, wherein the P-type work function pattern includes at least one of a titanium nitride film (TiN), a tantalum nitride film (TaN), a titanium oxynitride film (TiON), a titanium silicon nitride film (TiSiN), a titanium aluminum nitride film (TiAlN), a tungsten carbon nitride film (WCN), and a molybdenum nitride film (MoN), and
the first N-type work function pattern and the second N-type work function pattern each include at least one of aluminum-doped titanium carbide (TiAlC), aluminum-doped tantalum carbide (TaAlC), aluminum-doped vanadium carbide (VAlC), aluminum and silicon-doped titanium carbide (TiAlSiC), and aluminum and silicon doped tantalum carbide (TaAlSiC).

20. The semiconductor device of claim 15, wherein a thickness of the diffusion prevention pattern is 3 Å or more and 10 Å or less.
